(19) United States
(12) Patent Application Publication
(10) Pub. No.: US 2025/0260334 A1
(43) Pub. Date: Aug. 14, 2025

(54) INVERTER ASSEMBLY FOR ELECTRIC VEHICLES

(71) Applicant: Strelar, Inc., Bronx, NY (US)

(72) Inventors: Ondrej SEREDA, Prague (CZ); Marek MILTNER, Palo Alto, CA (US); Jan PLESNIK, Prague (CZ); Derrick Harry LEWIS, New York, NY (US)

(21) Appl. No.: 18/440,127

(22) Filed: Feb. 13, 2024

(51) Int. Cl. H02M 7/00; H05K 7/20

(52) U.S. Cl. CPC H02M 7/003; H05K 7/20254; H05K 7/20927

(57) ABSTRACT

An inverter assembly is described. In some embodiments, the inverter assembly includes a laminated housing (and associated laminated front panel) that is sized to contain electrical components of the inverter assembly. Further, the inverter assembly can include a cooling plate, adapted to operate as a heat sink, for such a package of components. The cooling plate may be disposed within the housing to efficiently remove heat from the inside of the laminated housing, such as proximate to multiple power boards that support power transistors.

### BACKGROUND

The utilization of inverters for electric vehicles is often limited by requirements and/or constraints imposed by the automotive industry and associated regulatory entities. For example, issues arise when providing thermal management during operation of inverters, especially when the size and/or weight of the inverter is optimized to support high performance vehicles, such as racing vehicles.

For example, a typical inverter assembly is designed to protect internal components of an inverter from damage due to mechanical forces, impacts, thermal effects, and so on. Inverters can be constructed using materials that balance strength with weight, such as aluminum and/or composites, to ensure structural integrity. Further, inverters often include cooling components, such as components that provide liquid cooling, heat sinks, and so on, which can operate to dissipate heat from areas within the inverters.

Thus, while such inverter assemblies utilize various components to attempt to realize lower weight with enhanced protection, further efforts and enhanced designs may lead to continued optimization and efficiencies for inverter assemblies, such as assemblies utilized by high performance vehicles.

### BRIEF DESCRIPTION OF THE DRAWINGS

Embodiments of the present technology will be described and explained through the use of the accompanying drawings.

FIGS. 1A-1B are diagrams illustrating an exploded view of an inverter assembly.

FIG. 2 is a diagram illustrating an inverter assembly.

FIG. 3A is a diagram illustrating a top view of an inverter assembly.

FIG. 3B is a diagram illustrating a bottom view of an inverter assembly.

FIG. 4 is a diagram illustrating a cooling plate for an inverter assembly.

FIG. 5 is a flow diagram illustrating a method of assembling an inverter for an electric vehicle.

In the drawings, some components are not drawn to scale, and some components can be combined for discussion of some of the implementations of the present technology. Moreover, while the technology is amenable to various modifications and alternative forms, specific implementations have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

### Overview

An inverter assembly for an electric vehicle is described. The inverter assembly include a three-dimensional (3D) printed cooling plate, which can be disposed, placed, and/or positioned proximate to MOSFETs (metal-oxide-semiconductor-field-effect-transistors) and other devices that generate AC current within the assembly.

Such devices, which may be part of power boards or other similar components, generate significant amounts of heat during operation, especially when the assembly is a dual inverter assembly, such as an assembly that outputs AC current to two motors (e.g., traction motors) of an electric vehicle. The cooling plate, therefore, is positioned and/or shaped to flow liquid coolant (e.g., water) across or within the inverter assembly at various working points, which dissipates heat from the working points to maintain an internal operational temperature within desired ranges.

The inverter assembly, in some embodiments, includes a laminated housing (and associated laminated front panel) that is sized to contain the electrical components of the inverter assembly. The cooling plate, therefore, is adapted to operate as a heat sink for such a package of components and is disposed to efficiently remove heat from the inside of the laminated housing. The inverter assembly can utilize a lightweight, laminated housing having a dual inverter configuration, enabling the inverter assembly to provide a high power-to-weight ratio for its output power. An electric vehicle having such an inverter may realize enhanced acceleration and/or speed capabilities, among other benefits.

While the inverter assemblies are described with respect to, or for use by, an electric vehicle (e.g., a high-performance EV), the inverter assemblies described herein can be configured or utilized with other devices having electric motors or drivetrains, such as electric trains, airplanes, boats, and so on.

Various embodiments of the technology will now be described. The following description provides specific details for a thorough understanding and an enabling description of these embodiments. One skilled in the art will understand, however, that these embodiments may be practiced without many of these details. Additionally, some well-known structures or functions may not be shown or described in detail, so as to avoid unnecessarily obscuring the relevant description of the various embodiments. The terminology used in the description presented below is intended to be interpreted in its broadest reasonable manner, even though it is being used in conjunction with a detailed description of certain specific embodiments.

### Examples of the Inverter Assembly

As described herein, an inverter assembly for use with an electric vehicle, such as electric vehicle having two or more traction motors, is described. For example, EVs employ traction motors to independently control each wheel of the vehicle, resulting in optimized handling and performance. However, such EVs utilize multiple inverters (e.g., one for each motor), and the sharing of a direct current (DC) link by two or more inverters can lead to various issues, such as issues associated with the accuracy of current measurements.

A dual inverter assembly can mitigate such issues, because multiple motors are synchronized and controlled via a single MCU (microcontroller) or control board (e.g., current measurements are performed at certain times, such when power transistors are not switching). Thus, a dual inverter assembly can provide noiseless current measurements, resulting in enhanced precision and better vehicle performance, among other benefits.

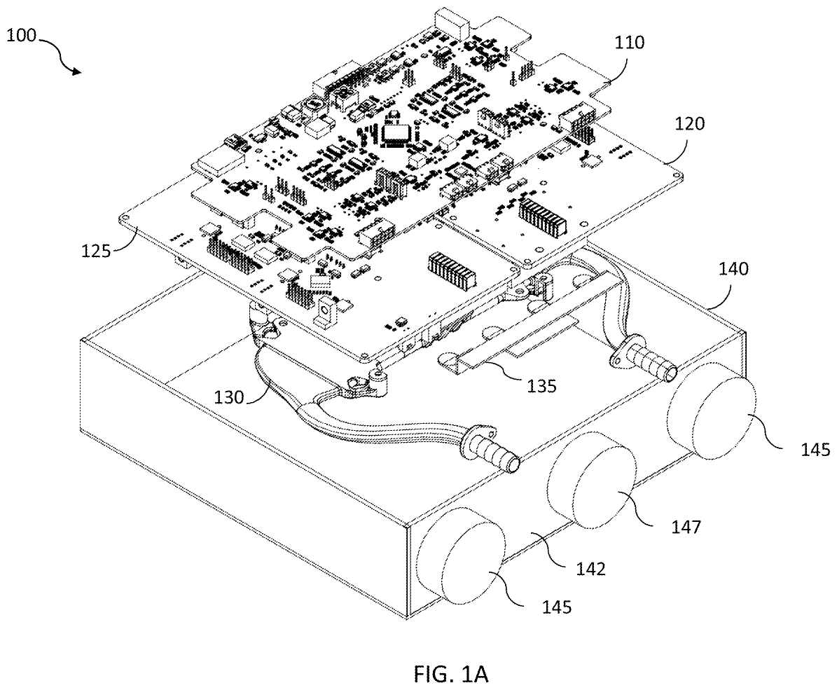

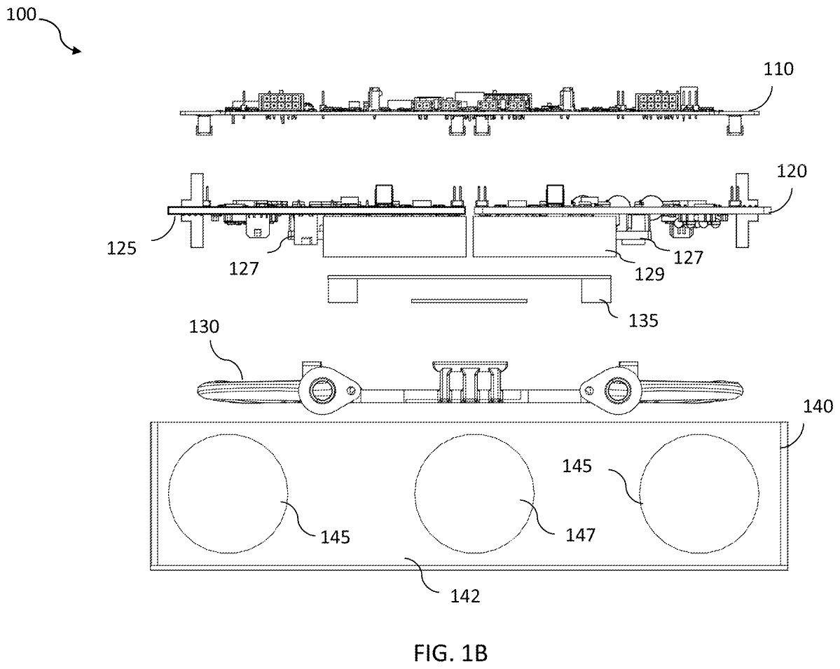

FIGS. 1A-1B are diagrams illustrating an exploded view of an inverter assembly 100. The inverter assembly 100 includes a control board 110 disposed above or on top of dual power boards 120, 125. As shown, the control board 110 has an orientation that is perpendicular to an orientation of the power boards 120, 125. The power boards 120, 125 include power MOSFETs 127, which connect or couple to the control board via B2B (board to board) connectors. The MOSFETs 127 may be positioned on the inside of DC link capacitors 129. Further, the power boards 120, 125 can include a capacitor bank or banks, which may absorb or mitigate ripple currents during operation.

Bus bars 135 (e.g., a positive and a negative bus bar) provides a high voltage coupling between the control board 110 and the MOSFETs 127 of the power boards 120, 125. A cooling plate 130 is disposed proximate to the MOSFETs 127, such as below or under the power boards 120, 125. As described herein, the cooling plate 130 may be a 3D printed aluminum structure having a shape that enables liquid coolant to flow within the inverter assembly 100 near the MOSFETs 127 and other devices that generate heat during operation.

The components of the inverter assembly 100 are attached or otherwise coupled to a front panel 142 of a housing 140. The housing 140 and/or the front panel 142 may be laminated and formed of aluminum or a composite material. The front panel 142 may be detachable, to facilitate simple disassembly. In some cases, the housing 140 may provide and/or include EMC shielding. For example, the housing 140 may include a mesh or mesh layer that is also laminated.

The front panel 142 includes connectors, such as a high voltage direct current (DC) connector 145 (e.g., which connects the inverter assembly 100 to a DC power source, such as a battery pack), and two alternating current (AC) connectors 147 (e.g., which connect the inverter assembly 100 to motors).

In some embodiments, the inverter assembly can be a high-performance dual motor inverter (2×3 phase). The inverter can operate on a DC Link voltage of 800V with continuous 100 A (80 kW per channel), designed for a 600V accumulator and 35 kWp motor. In some cases, the inverter assembly can accommodate higher voltages (e.g., via the use of power MOSFETs rated up to 1200V), such as voltages reaching 800V, which aligns with certain voltage architectures (e.g., 800V/400V).

Thus, the inverter assembly 100, via the power MOSFETs, can deliver 80 kWp of power to the motors of an electric vehicle, despite the assembly being a lightweight stack of boards in a laminated housing. For example, the power boards 120, 125 can be PCBs that include specialized 600 μm copper layers, which are able to 100 A continuously during operation (e.g., under high-temperature operating conditions). Thus, the inverter assembly 100 can provide high amounts of power during operation because the cooling plate is positioned and configured to dissipate heat in an efficient and effective manner.

In some cases, the power MOSFETs are formed of Silicon Carbide (SiC), which can provide a higher operational temperature range compared to other devices (e.g., IGBTs). Further, SiC MOSFETs may reduce switching losses, enhancing the overall efficiency of the inverter assembly 100.

The cooling plate 130 is formed of lightweight materials, such as 3D printed aluminum or other composite materials, which facilitates the overall weight of the inverter assembly 100 to be lower, leading to higher performances at certain power levels. For example, using Computational Fluid Dynamics (CFD) optimization, the inverter assembly 100 can create an even temperature distribution or gradient along one direction of the assembly (e.g., across a long axis, such as from a left side to a right side, of the assembly).

For example, the inverter assembly 100, employing the components described herein, can have a weight under 2 kg (under 4.5 lbs.), and have a size that is 25 cm by 26 cm by 5 cm, while providing a >10 kW/I (e.g., such as 49 kW/I) power-to-volume ratio.

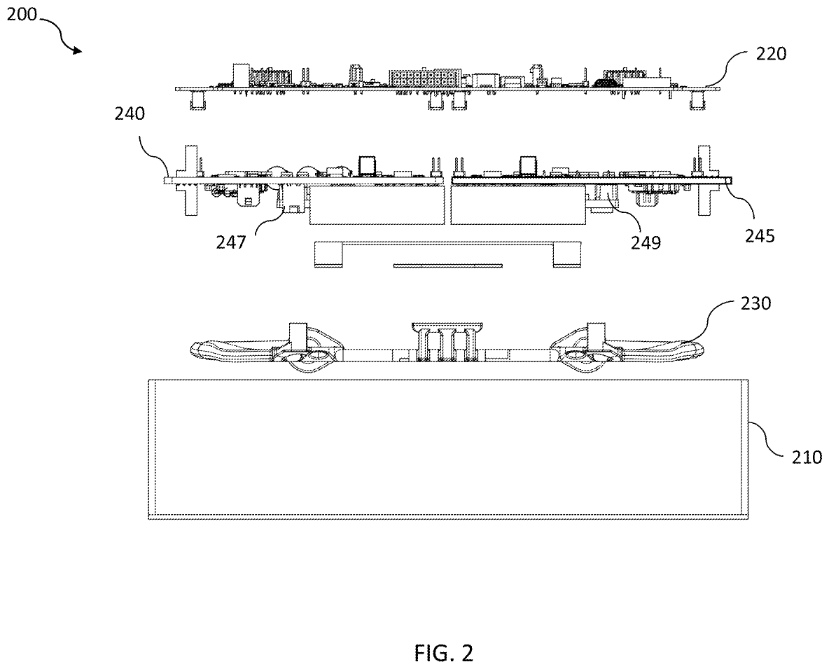

FIG. 2 presents an example inverter assembly 200. The inverter assembly 200 includes a laminated housing 210 that contains a control board 220, a cooling plate 230, a first power board 240, and a second power board 245. The first power board 240 has a first MOSFET device 247, and the second power board 245, disposed proximate to the first power board 240, has a second MOSFET device 249. The control board is disposed on top of or above the first power board 240 and the second power board 245, and the cooling plate 230 is disposed under the first power board 240 and the second power board 245. Although not shown, the housing 210 may include a laminated front panel having external connectors coupled to the first power board 240 and the second power board 245.

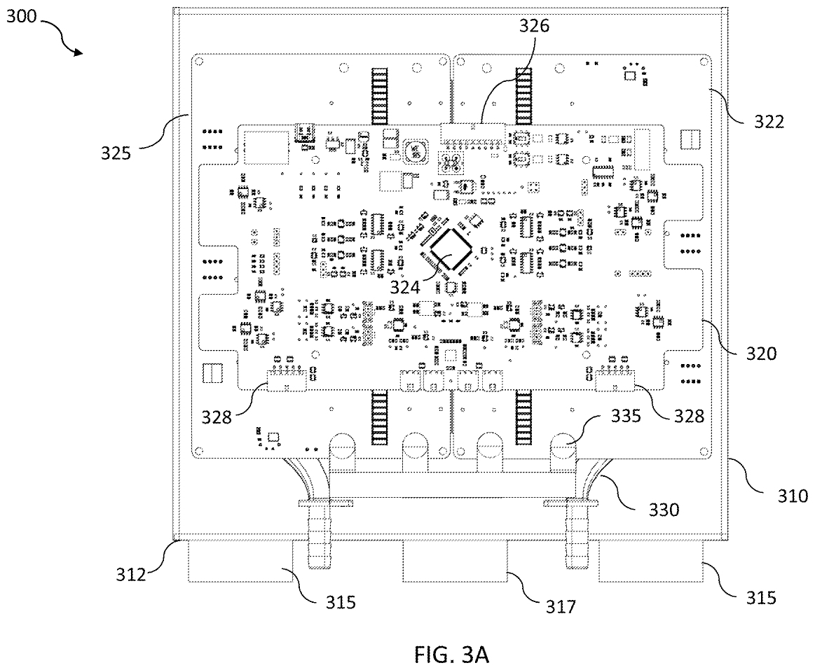

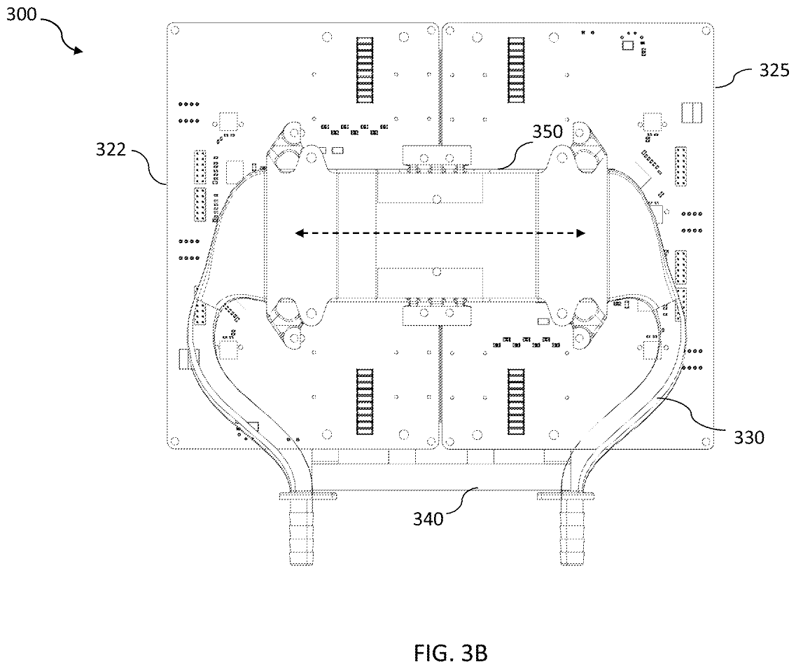

FIG. 3A depicts a top view of an inverter assembly 300. The inverter assembly 300 includes a laminated housing 310 that contains a control board 320, a first power board 322, a second power board 325, and a cooling plate 330. Bus bars 335, 340 provide a high voltage connection between MOSFET devices of the power boards 320, 322 and the control board 320. In some cases, the first power board 322 and the second power board 325 are disposed in an orientation that is perpendicular to an orientation of the control board 320.

The laminated housing 310 includes a laminated front plate (or panel) 312, which provides connectors between the inverter assembly 300 and external components, such as components of an electric vehicle. For example, external connectors of the laminated front panel 312 include a direct current (DC) connector 317 that couples the inverter assembly 300 to an electric battery or battery pack of an electric vehicle, and alternating current (AC) connectors 315 that couple the inverter assembly 300 electric motors of the electric vehicle.

The control board 320 includes a main controller 324, an LV (low voltage) connector 326, and resolver connectors 328. The underside of the control board 320 (not shown) includes several B2B connectors, as described herein.

FIG. 3B is a diagram illustrating a bottom view of the inverter assembly 300. A flat reservoir or central section 350 of the cooling plate 330 is disposed proximate to power MOSFETs (e.g., located under the central section 350) of the power boards 322, 325, to facilitate the dissipation of heat generated by the MOSFETs during operation. Thus, in some cases, the first power board 322 and the second power board 325 are disposed in an orientation that is perpendicular to a flow of liquid coolant (e.g., shown by the dotted arrow) within the cooling plate 330. The cooling plate 330 can be a three-dimensional (3D) printed structure formed of aluminum or an aluminum composite material.

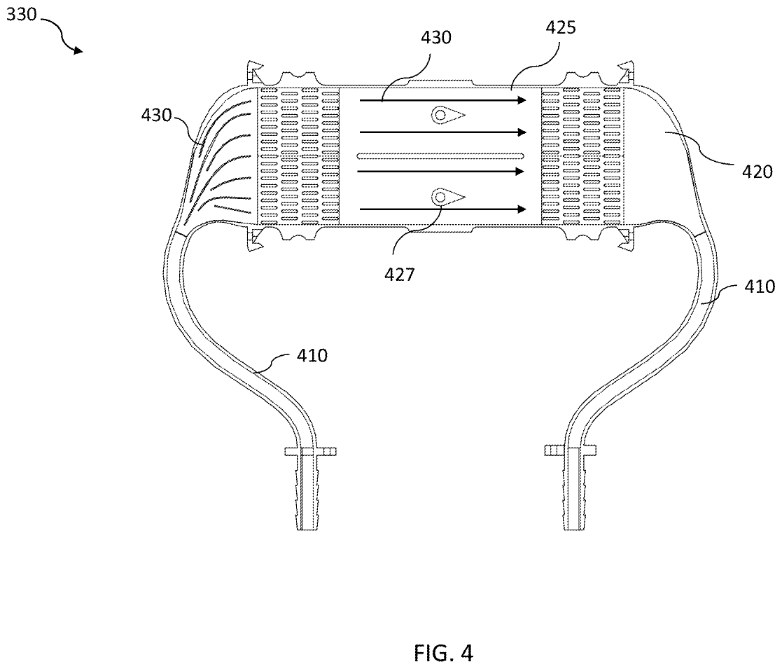

FIG. 4 is a diagram illustrating the cooling plate 330 for the inverter assembly 300. The cooling plate can include arms 410, which intake and output coolant, and a central or flat reservoir 420, which facilitates the flow of a liquid coolant 430 (e.g., water) across the inverter assembly 300. In some cases, the cooling plate 330, via the reservoir 420, may include multiple cooling channels 425 and/or fins 427, configured to facilitate the flow of the liquid coolant 430 across a long direction of the inverter assembly 300 within the cooling plate 330.

In some cases, the inverter assembly 300, as shown provides all connections at one location of the assembly, such as at a front area of the assembly. Such a configuration enables the inverter assembly 300 to be compact and lightweight and facilitates coupling to various components of an EV (e.g., water source, battery pack, motors) in an efficient and east manner.

Further, in some embodiments, the inverter assembly 100 provides a remote or external discharge function, where the assembly can employ a discharge mechanism to discharge voltage from its DC link capacitors using external logic. For example, the power board 322, 325 may include a discrete transistor in a closed state (e.g., depletion NMOS) and a resistor coupled to the cooling plate (e.g., a heat sink). The resistor may discharge voltage from the DC link capacitors, and a photovoltaic optocoupler can turn off the discrete transistors via an external or remote signal.

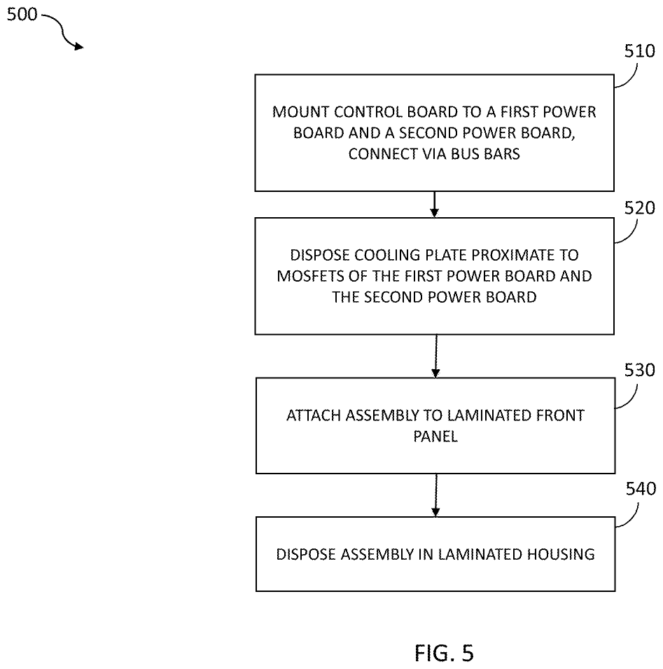

FIG. 5 is a flow diagram illustrating a method 500 of assembling an inverter for an electric vehicle. In step 510, a control board is mounted to a first power board and a second power board via a bus bar. In step 520, a cooling plate is placed or disposed under the first power board and the second power board. In step 530, the mounted control board, the first power board, the second power board, and the cooling plate are attached to a laminated front panel of the laminated housing. In step 540, the assembly is placed within a laminated housing. In some cases, the first power board and the second power board are disposed in an orientation that is perpendicular to an orientation of the control board.

Thus, in various embodiments, an enhanced inverter assembly is described, such as an inverter that operates with an electric vehicle having two traction motors, and includes a first power board configured to provide alternating current (AC) power to a first traction motor, a second power board configured to provide AC power to a second traction motor, and a cooling plate disposed under the first power board and the second power board.

### Example Embodiments of the Inverter Assembly

As described herein, the inverter assembly may be implemented as various embodiments. For example, an inverter assembly includes a first power board having a first MOSFET device, a second power board, disposed proximate to the first power board, having a second MOSFET device, a control board disposed on top of the first power board and the second power board, a cooling plate disposed under the first power board and the second power board, and a laminated housing that contains the first power board, the second power board, the control board, and the cooling plate, and a laminated front panel having external connectors coupled to the first power board and the second power board.

The cooling plate may include a flat reservoir section that is placed between the first MOSFET device and the second MOSFET device.

The first power board and the second power board may be disposed in an orientation that is perpendicular to an orientation of the control board.

The first power board and the second power board may be disposed in an orientation that is perpendicular to a flow of liquid coolant within the cooling plate.

The cooling plate may include multiple cooling channels configured to facilitate a flow of liquid coolant across a long direction of the inverter assembly within the cooling plate.

The external connectors of the laminated front panel may include a direct current (DC) connector that couples the inverter assembly to an electric battery of an electric vehicle, a first alternating current (AC) connector that couples the inverter assembly to a first electric motor of the electric vehicle, and a second AC connector that couples the inverter assembly to a second electric motor of the electric vehicle.

The cooling plate may include a three-dimensional (3D) printed structure formed of aluminum or an aluminum composite material.

The laminated housing and the laminated front panel may be formed of aluminum or an aluminum composite material.

The inverter assembly may also include a bus bar that connects the first MOSFET device and the second MOSFET device to the control board.

The first MOSFET and the second MOSFET may be silicon carbide MOSFETs.

As another example, an inverter for an electric vehicle having two traction motors includes a first power board configured to provide alternating current (AC) power to a first traction motor, a second power board configured to provide AC power to a second traction motor, and a cooling plate disposed under the first power board and the second power board.

The inverter may include a control board disposed on top of the first power board and the second power board and coupled to the first power board and the second power board via a bus bar.

The inverter may include a laminated housing that contains the first power board, the second power board, and the cooling plate.

The inverter may include a laminated front panel having external connectors coupled to the first power board and the second power board.

The cooling plate may include a flat reservoir section that is placed between the first MOSFET device and the second MOSFET device.

The first power board and the second power board may be disposed in an orientation that is perpendicular to a flow of liquid coolant within the cooling plate.

The cooling plate may include multiple cooling channels configured to facilitate a flow of liquid coolant across a long direction of the inverter within the cooling plate.

The cooling plate may be a three-dimensional (3D) printed structure formed of aluminum or an aluminum composite material.

As another example, a method of assembling an inverter includes mounting a control board to a first power board and a second power board via a bus bar, disposing a cooling plate under the first power board and the second power board, disposing the mounted control board, the first power board, the second power board, and the cooling plate within a laminated housing and attaching the first power board and the second power board to a laminated front panel of the laminated housing.

The first power board and the second power board may be disposed in an orientation that is perpendicular to an orientation of the control board.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or”, in reference to a list of two or more items, covers all of the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for, the disclosure are described above for illustrative purposes, various equivalent modifications are possible within the scope of the disclosure, as those skilled in the relevant art will recognize.

The teachings of the disclosure provided herein can be applied to other systems, not necessarily the system described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the electric bike and bike frame may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

From the foregoing, it will be appreciated that specific embodiments have been described herein for purposes of illustration, but that various modifications may be made without deviating from the spirit and scope of the embodiments. Accordingly, the embodiments are not limited except as by the appended claims.

What is claimed is:

1. An inverter assembly, comprising:
a first power board having a first MOSFET device;
a second power board, disposed proximate to the first power board, having a second MOSFET device;
a control board disposed on top of the first power board and the second power board;
a cooling plate disposed under the first power board and the second power board;
a laminated housing that contains the first power board, the second power board, the control board, and the cooling plate; and
a laminated front panel having external connectors coupled to the first power board and the second power board.

2. The inverter assembly of claim 1, wherein the cooling plate includes a flat reservoir section that is placed between the first MOSFET device and the second MOSFET device.

3. The inverter assembly of claim 1 wherein the first power board and the second power board are disposed in an orientation that is perpendicular to an orientation of the control board.

4. The inverter assembly of claim 1 wherein the first power board and the second power board are disposed in an orientation that is perpendicular to a flow of liquid coolant within the cooling plate.

5. The inverter assembly of claim 1, wherein the cooling plate includes multiple cooling channels configured to facilitate a flow of liquid coolant across a long direction of the inverter assembly within the cooling plate.

6. The inverter assembly of claim 1, wherein the external connectors of the laminated front panel include:
a direct current (DC) connector that couples the inverter assembly to an electric battery of an electric vehicle;
a first alternating current (AC) connector that couples the inverter assembly to a first electric motor of the electric vehicle; and
a second AC connector that couples the inverter assembly to a second electric motor of the electric vehicle.

7. The inverter assembly of claim 1, wherein the cooling plate is a three-dimensional (3D) printed structure formed of aluminum or an aluminum composite material.

8. The inverter assembly of claim 1, wherein the laminated housing and the laminated front panel are formed of aluminum or an aluminum composite material.

9. The inverter assembly of claim 1, further comprising a bus bar that connects the first MOSFET device and the second MOSFET device to the control board.

10. The inverter assembly of claim 1, wherein the first MOSFET and the second MOSFET are silicon carbide MOSFETs.

11. An inverter for an electric vehicle having two traction motors, the inverter comprising:
a first power board configured to provide alternating current (AC) power to a first traction motor;
a second power board configured to provide AC power to a second traction motor; and
a cooling plate disposed under the first power board and the second power board.

12. The inverter of claim 11, further comprising a control board disposed on top of the first power board and the second power board and coupled to the first power board and the second power board via a bus bar.

13. The inverter of claim 11, further comprising a laminated housing that contains the first power board, the second power board, and the cooling plate.

14. The inverter of claim 11, further comprising a laminated front panel having external connectors coupled to the first power board and the second power board.

15. The inverter of claim 11, wherein the cooling plate includes a flat reservoir section that is placed between the first MOSFET device and the second MOSFET device.

16. The inverter of claim 11, wherein the first power board and the second power board are disposed in an orientation that is perpendicular to a flow of liquid coolant within the cooling plate.

17. The inverter of claim 11, wherein the cooling plate includes multiple cooling channels configured to facilitate a flow of liquid coolant across a long direction of the inverter within the cooling plate.

18. The inverter of claim 11, wherein the cooling plate is a three-dimensional (3D) printed structure formed of aluminum or an aluminum composite material.

19. A method of assembling an inverter, the method comprising:
mounting a control board to a first power board and a second power board via a bus bar;
disposing a cooling plate under the first power board and the second power board;
attaching the first power board and the second power board to a laminated front panel of a laminated housing; and
disposing the mounted control board, the first power board, the second power board, and the cooling plate within the laminated housing.

20. The method of claim 19, wherein the first power board and the second power board are disposed in an orientation that is perpendicular to an orientation of the control board.
